(19) United States
(12) Patent Application Publication
(10) Pub. No.: US 2012/0080986 A1
(43) Pub. Date: Apr. 5, 2012

(54) COMPUTER ENCLOSURE

(75) Inventors: XIAN-GUANG TAN, Shenzhen City (CN); ZHEN-XING YE, Shenzhen City (CN)

(73) Assignees: HON HAI PRECISION INDUSTRY CO., LTD., Tu-Cheng (TW); HONG FU JIN PRECISION INDUSTRY (ShenZhen) Co., LTD, Shenzhen City (CN)

(21) Appl. No.: 12/910,855

(22) Filed: Oct. 24, 2010

(30) Foreign Application Priority Data
Sep. 30, 2010 (CN) 201010298706.2

(51) Int. Cl. H05K 5/02

(52) U.S. Cl. 312/319.1; 312/294

(57) ABSTRACT

A computer enclosure includes a chassis and a movable assembly. The chassis defines an opening. Two blocking pieces extend from the chassis at opposite sides of the opening. The movable assembly includes a post movably mounted to the chassis, and a closing member extending from a first end of the post and located between the blocking pieces to cover or uncover the opening with moving of the post.

### BACKGROUND

1. Technical Field

The present disclosure relates to a computer enclosure.

2. Description of Related Art

To test operating temperatures of components in a computer probes with cables attached to measuring devices are inserted into the enclosure of the computer containing the components. To give access to the cables an opening must be made in the enclosure. The opening may affect the structure of the enclosure and the airflow inside it and influence other tests such as vibration testing. However, sealing the opening may be inconvenient as the access hole may be needed again later.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial, assembled, isometric view of an exemplary embodiment of a computer enclosure.

FIG. 2 is an exploded, isometric view of the computer enclosure of FIG. 1.

FIG. 3 is an enlarged view of the circled portion III of FIG. 2

FIG. 4 is an assembled, isometric view of the computer enclosure of FIG. 1.

FIG. 5 is an enlarged view of the circled portion V of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

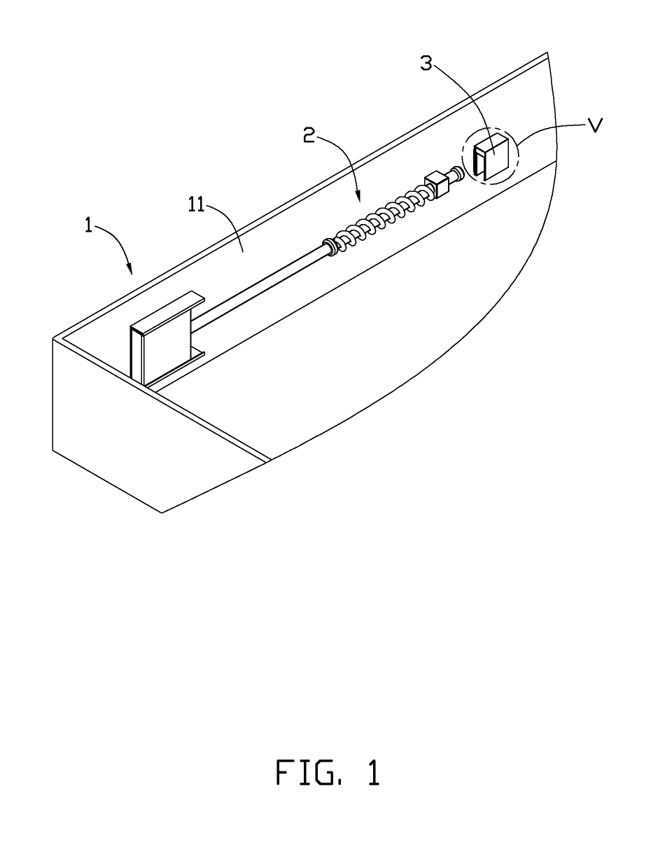

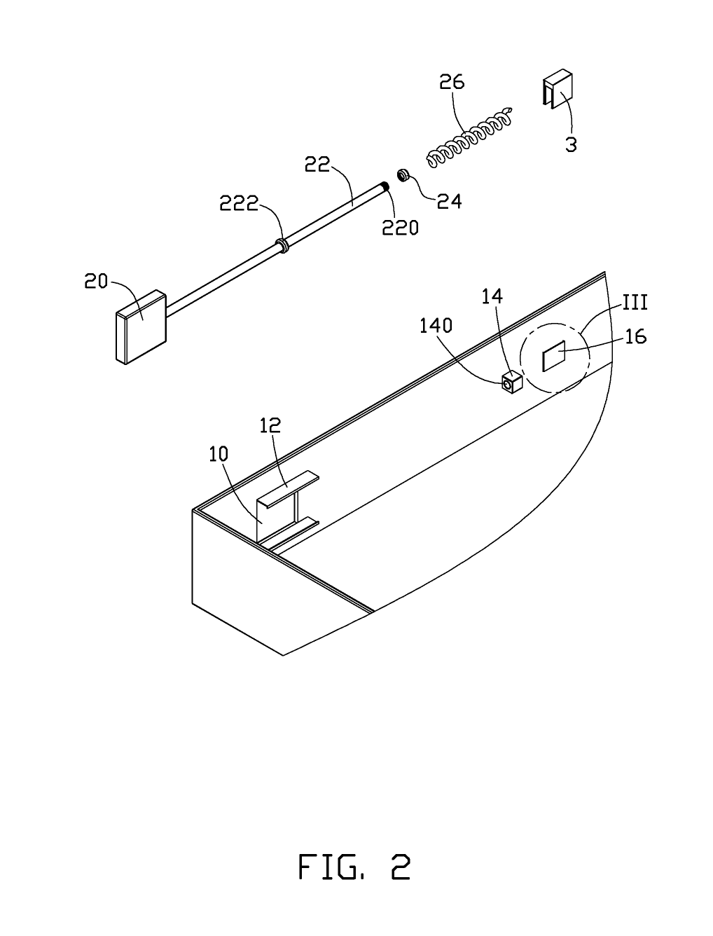

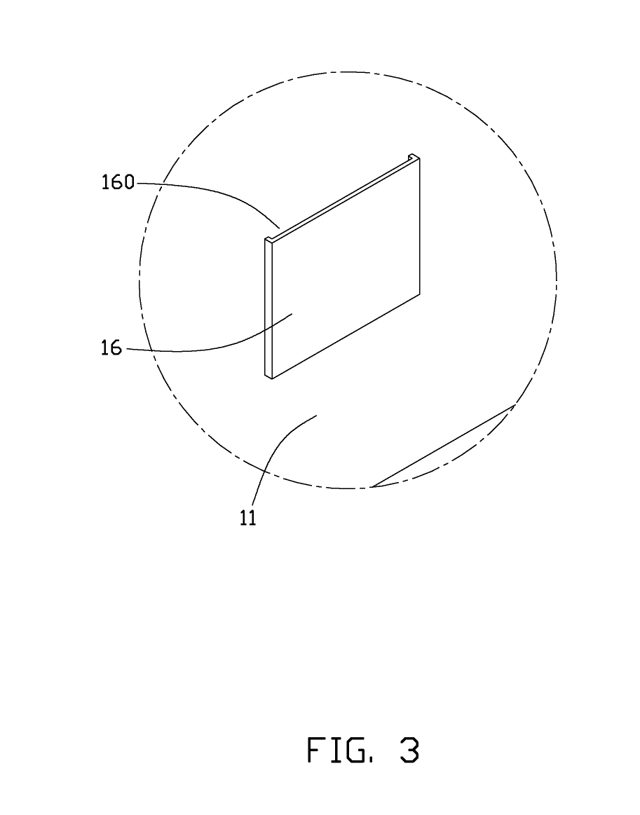

Referring to FIGS. 1 to 3, an exemplary embodiment of a computer enclosure includes a chassis 1, a movable assembly 2, and a fixing member 3.

The chassis 1 includes a sidewall 11. The sidewall 11 defines an opening 10 therein. A substantially bridge-shaped fastener 16 protrudes from the sidewall 11, opposite to the opening 10. A protrusion 14 protrudes from the sidewall 11, between the opening 10 and the fastener 16 but nearer the fastener 16. Two substantially L-shaped blocking pieces 12 perpendicularly extend from the sidewall 11, at opposite sides of the opening 10. The protrusion 14 defines a through hole 140 facing the opening 10. A receiving space 160 is bounded by the fastener 16 and the sidewall 11.

The movable assembly 2 includes a post 22 and a closing member 20 extending from a first end of the post 22. A threaded portion 220 is formed on a second end of the post 22 opposite to the first end. A detachable first blocking portion 24 can be screwed to the threaded portion 220 of the post 22. A second blocking portion 222 extends from a center of the post 22. In this embodiment, the first blocking portion 24 is a screw nut defining inner threads for engaging with the threaded portion 220 of the second end of the post 22.

The fixing member 3 includes a connection piece 30 and two side pieces 32 substantially perpendicularly extending from opposite sides of the connection piece 30. A substantially L-shaped inserting piece 34 extends from the outer surface of one of the side pieces 32 and bounds a receiving space 36 with this side piece 32.

Referring to FIG. 1 again, in assembly, the second end of the post 22 extends through a spring 26, and the through hole 140 of the protrusion 14, and then engages with the first blocking portion 24. The closing member 20 is located between the blocking pieces 12 to cover the opening 10. Opposite ends of the spring 26 resist again the second blocking portion 222 of the post 22 and the protrusion 14.

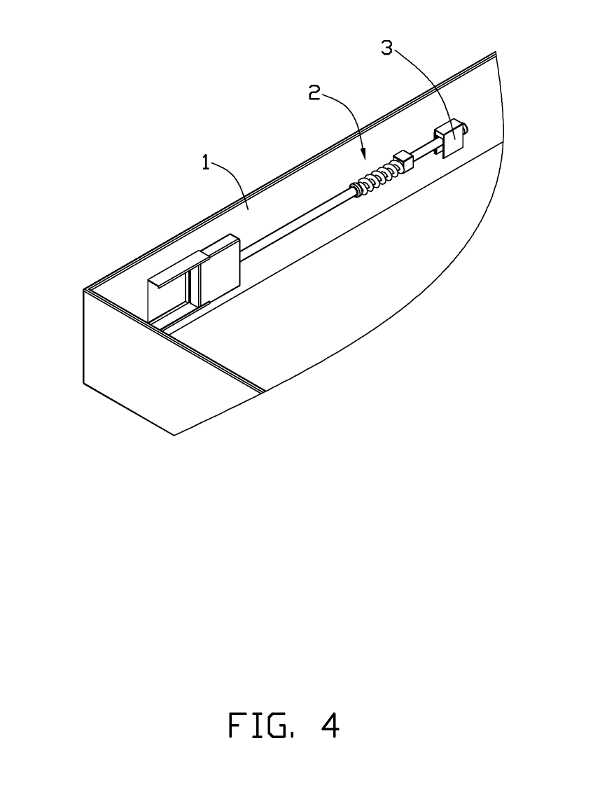

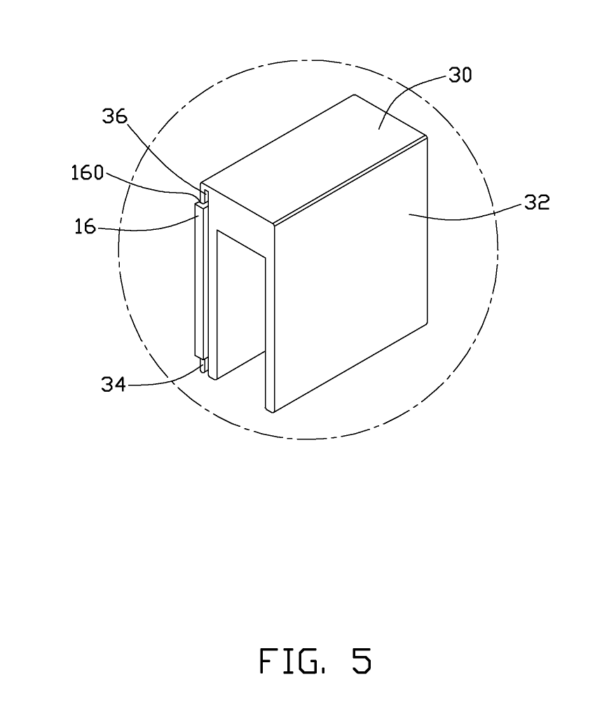

Referring to FIG. 4 and FIG. 5, in use, to uncover the opening 10, the post 22 is moved toward the fastener 16 until the second end of the post 22 passes by the fastener 16. The spring 26 is deformed, and the closing member 20 is moved away from the opening 10 to uncover the opening 10. The inserting piece 34 of the fixing member 3 nearby the receiving space 36 is inserted into the receiving space 160 between the sidewall 11 and the fastener 16, with the fastener 16 received in the receiving space 36. The post 22 is located between the side pieces 32 of the fixing member 3, and the first blocking portion 24 of the post 22 is blocked by one side of the fixing member 3 away from the opening 10.

To cover the opening 10, the fixing member 3 is disengaged from the fastener 16; the spring 26 is restored to drive the post 22 to cover the opening 10 with the closing member 20.

In other embodiments, the inserting piece 34 of the fixing member 3 can be omitted. In this embodiment, a side piece 32 of the fixing member 3 is inserted into the receiving space 160, and the post 22 is located between the other side piece 32 and the fastener 16.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A computer enclosure, comprising:
a chassis comprising a sidewall that defines an opening, two blocking pieces extending from the sidewall at opposite sides of the opening; and
a movable assembly comprising a post movably mounted to the sidewall, and a closing member extending from a first end of the post and located between the blocking pieces, to cover or uncover the opening with moving of the post.

2. The computer enclosure of claim 1, wherein a protrusion extends from the sidewall away from the opening, a second end of the post opposite to the first end movably extends through the protrusion.

3. The computer enclosure of claim 2, wherein a through hole facing the opening is defined in the protrusion through which the second end of the post movably extends, a blocking portion is detachably fixed to the second end of the post.

4. The computer enclosure of claim 2, further comprising a fixing member, wherein a fastener extends from the sidewall nearby the protrusion and opposite to the opening about the protrusion, the fixing member is fixed to the fastener, the second end of the post extends through the fixing member in response to the closing member moving with the post to uncover the opening of the sidewall.

5. The computer enclosure of claim 4, wherein the fixing member comprises a connection piece and two side pieces substantially perpendicularly extending from opposite sides of the connection piece, one of the side pieces is fixed to the fastener.

6. The computer enclosure of claim 5, wherein the fastener is bridge-shaped, with a first receiving space defined between the sidewall and the fastener, an inserting piece extends from the side piece nearby the fastener, with a second receiving space defined between the inserting piece and the corresponding side piece, wherein the inserting piece is inserted in the first receiving space, and the fastener is inserted in the second receiving space.

7. The computer enclosure of claim 2, further comprising an elastic member, wherein a blocking portion extends from a center of the post, the elastic member fits about the post, and resists against the blocking portion and the protrusion, to bias the post to move, thereby driving the post to cover the opening.
